(19) United States
(12) Patent Application Publication
(10) Pub. No.: US 2014/0332073 A1
(43) Pub. Date: Nov. 13, 2014

(54) SOLAR MODULE HAVING UNIFORM LIGHT

(71) Applicant: SOUTHERN TAIWAN UNIVERSITY OF SCIENCE AND TECHNOLOGY, TAINAN CITY (TW)

(72) Inventors: RUEI-TANG CHEN, TAINAN CITY (TW); CHONG-YOU LIAO, TAINAN CITY (TW); HONG-MING SYU, TAINAN CITY (TW); LIEN-YI WANG, TAINAN CITY (TW)

(73) Assignee: SOUTHERN TAIWAN UNIVERSITY OF SCIENCE AND TECHNOLOGY, TAINAN CITY (TW)

(21) Appl. No.: 14/272,819

(22) Filed: May 8, 2014

(30) Foreign Application Priority Data
May 13, 2013 (TW) 102116866

(51) Int. Cl. H01L 31/048

(52) U.S. Cl. CPC H01L 31/048
USPC 136/258; 136/259

(57) ABSTRACT

A solar module having uniform light for assembling on the top of a building to act as a roof is revealed. It comprises a transparent substrate, at least one solar chip, a hot melt adhesive film, a transparent cover plate, and a diffusion film disposed between the transparent substrate and the solar chip.

### BACKGROUND OF THE INVENTION

1. Fields of the Invention

The present invention relates to a solar module having uniform light. It can be utilized in a solar module which provides illumination to the plants in a plant factory. The film of solar panels added with scattering particles allows the solar panels to have uniform light transmittance, so that the plants can obtain uniform illumination.

2. Descriptions of Related Art

In the era of population explosion, the population has rapidly increased from 2 billion to more than 7 billion and will probably exceed 10 billion in the foreseeable future. However, food supply became hard to keep up with demand for people due to a gradual loss of agricultural land used for residential and industrial development. Furthermore, there are much more people began to turn to traditional Chinese medicine, resulting in an increased demand for Chinese medicinal herb in recent years. In such a case, sufficient sunlight and water is an urgent need for plants. Light intensity required for plants is not identical. Some plants must be grown in greenhouses, so it is imperative to set up factories to properly cultivate various plants according to light intensity they require.

In order to save electricity and promote green energy, plant factories usually use solar panels. For instance, a Taiwan Patent No. I365711, issued on 10 Jul. 2009, has disclosed a solar energy greenhouse, comprising a main structure, a roof structure disposed in the main structure and a plurality of the thin film solar cells disposed on the roof structure, wherein the intervals between the plurality of the thin film solar cells are different. Accordingly, the thin film solar cells can absorb sunlight and generate electrical energy. In the aforementioned description, the intervals between the plurality of thin film solar cells are determined by an irradiation angle of sunlight or by a location of plants placed in a solar energy greenhouse. Therefore, the thin film solar cells can adjust the angle of inclination, allowing sunlight to vertically irradiate on the thin film solar cells and using sunlight as a power source. The intervals between the thin film solar cells are mad from a transparent material so that sunlight can penetrate it and irradiate the solar energy greenhouse, while the area sheltered by the thin film solar cells are not transparent so that sunlight cannot reach the solar energy greenhouse, causing a problem of insufficient light. Accordingly, the traditional solar panels used in the plant factory have a disadvantage of uneven illumination. To solve the problem, additional fluorescent lamps or LEDs are required for enhancing brightness, which is inconsistent with the original concept of energy saving for disposing solar panels.

### SUMMARY OF THE INVENTION

In view of the above-mentioned problems, the object of the present invention is to provide a solar module having uniform light. It can be utilized in a solar module in a plant factory using both of sunlight and artificial light, in architecture industry (e.g. light absorption hoods), and in livestock industry (e.g. farmhouse). The diffusion film of solar panels added with scattering particles allows the solar panels to have uniform light transmittance, so that the plants can obtain uniform illumination.

Disclosed herein is a solar module having uniform light which can be disposed on the top of a building (e.g. greenhouse) to act as a roof (e.g. shading hood). The solar module having uniform light comprises a transparent substrate, at least one solar chip, a hot melt adhesive film, a transparent cover plate, and a diffusion film disposed between the transparent substrate and the solar chip. Accordingly, when sunlight transmits to a light transmittable region, the diffusion film can scatter sunlight on the opaque region sheltered by the solar chip to generate a uniform light.

According to an embodiment of the present invention, the light transmittable region has a transmittance of 20% to 99% and a haze of 10 Haze to 99 Haze.

According to an embodiment of the present invention, the solar chip is selected from a group III-V solar chip, a monocrystalline silicon solar chip, a polycrystalline silicon solar chip or a CIGS solar chip.

According to an embodiment of the present invention, the transparent cover plate disposed on a sunlight incident plane is an ironless glass having a thickness less than 1 mm, and the transparent substrate is a transparent plastic film selected from a material of polyethylene terephthalate, acrylic, polycarbonate, polytetrafluoroethylene resin or ethylene-tetrafluoroethylene.

According to an embodiment of the present invention, the diffusion film is made from a hot melt adhesive added with scattering particles, and the hot melt adhesive is selected from a material of polyethylene vinyl acetate resin, acrylic, polycarbonate or polyurea.

According to an embodiment of the present invention, the solar module is combined with a lightweight frame assembled on the roof of building, and the lightweight frame is provided with a groove corresponding to the assembly of the solar module.

According to an embodiment of the present invention, the light transmittable region accounts for 5% to 70% of the area of the solar module.

According to an embodiment of the present invention, the solar module can be utilized in buildings, e.g. bus station and parking lot, or can act as a solar power module.

According to an embodiment of the present invention, the solar module connects in parallel with the supply mains and acts as an electric power source to provide objects (e.g. LEDs) in need of electric power.

### BRIEF DESCRIPTION OF THE DRAWINGS

FIG. 1 is a schematic diagram showing a solar module having uniform light in assembly;

FIG. 2 is a cross-sectional view showing a solar module having uniform light according to the present invention;

FIG. 3 is a plane view showing a solar module having uniform light according to the present invention;

FIG. 4 is a schematic diagram showing a micro structure according to the present invention;

FIG. 5 is another schematic diagram showing a micro structure according to the present invention.

### DETAILED DESCRIPTION OF THE PREFERRED EMBODIMENT

Hereinafter, an exemplary embodiment of the present invention will be described in detail with reference to the accompanying drawings.

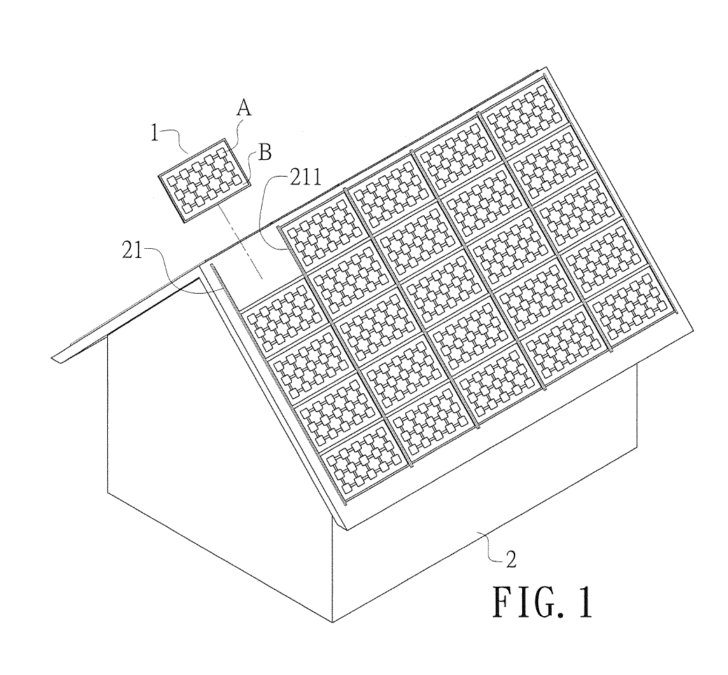

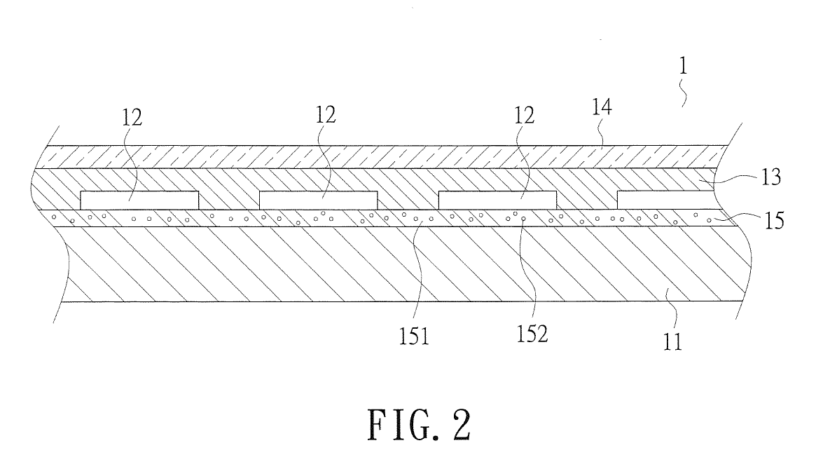

Referring to FIG. 1 and FIG. 2, a cross-sectional view and a plane view showing a solar module having uniform light according to the present invention are revealed. The solar module (1) having uniform light comprises a transparent substrate (11), at least one solar chip (12) arranged on the transparent substrate (11), a transparent cover plate (14) covered on the solar chip (12), a hot melt adhesive film (13) for packaging the solar chip (12) and the transparent cover plate (14), a diffusion film (15) disposed between the transparent substrate (11) and the solar chip (12), an opaque region (A) formed by sheltering of the solar chip (12), and a light transmittable region (B) surrounding the opaque region (A) without sheltering of the solar chip (12). Accordingly, when sunlight travels through a light transmittable region (B) of the solar module (1), the diffusion film (15) scatters sunlight to the opaque region (A) sheltered by the solar chip (12) to generate a uniform light.

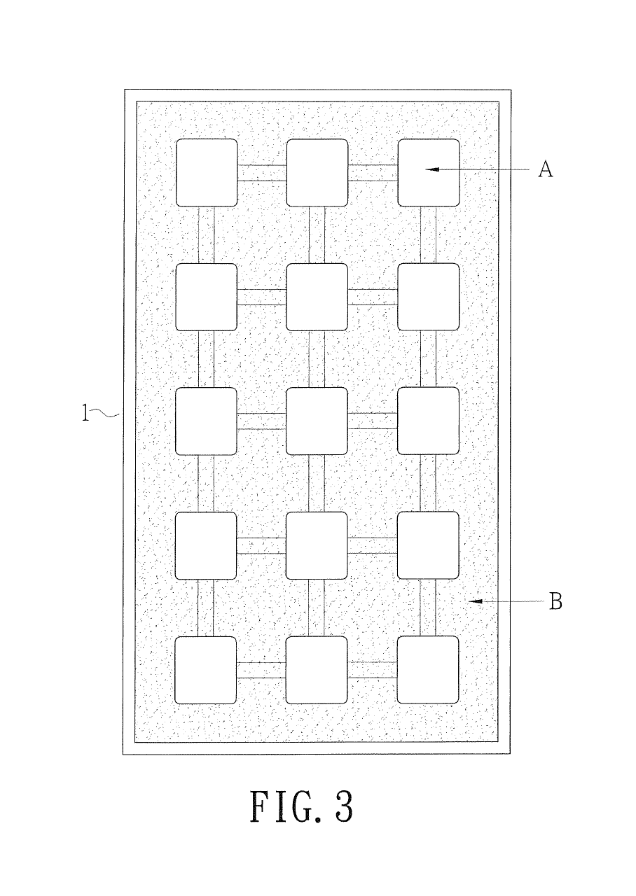

An exemplary embodiment of the present invention will be described with reference to FIG. 1 to FIG. 3. The solar module (1) can be disposed on a roof of a building (2) (e.g. houses, factories, greenhouses, plant factory and the like) and act as a roof or a shading hood. Moreover, it can be utilized in the buildings (2) in a public space, e.g. bus station and parking lot, or can act as a solar power module. When the solar module (1) is combined with a lightweight frame (21) assembled on the roof of a building (2), the lightweight frame (21) can be provided with a groove (211) corresponding to the assembly of the solar module (1). The solar module (1) is equipped with a light transmittable region (B) and an opaque region (A). The light transmittable region (B) has a transmittance of 20% to 99% and a haze of 10 Haze to 99 haze and accounts for 5% to 70% of the area of the solar module (1). The transparent cover plate (14) is an ironless glass having a thickness less than 1 mm, and the transparent substrate (11) is a transparent plastic film. Accordingly, when sunlight transmits to the light transmittable region (B), the diffusion film (15) can scatter it on the opaque region (A) sheltered by the solar chip (12), so as to generate a uniform light. The aforementioned transparent substrate (11) is a transparent plastic film selected from a material of polyethylene terephthalate, acrylic, polycarbonate, polytetrafluoroethylene resin or ethylene-tetrafluoroethylene. The solar chip (12) is selected from a group III-V solar chip, a monocrystalline silicon solar chip, a polycrystalline silicon solar chip or a CIGS solar chip. The diffusion film (15) is made from a hot melt adhesive (151) added with scattering particles (152), and the hot melt adhesive (151) is selected from a material of polyethylene vinyl acetate resin, acrylic, polycarbonate or polyurea.

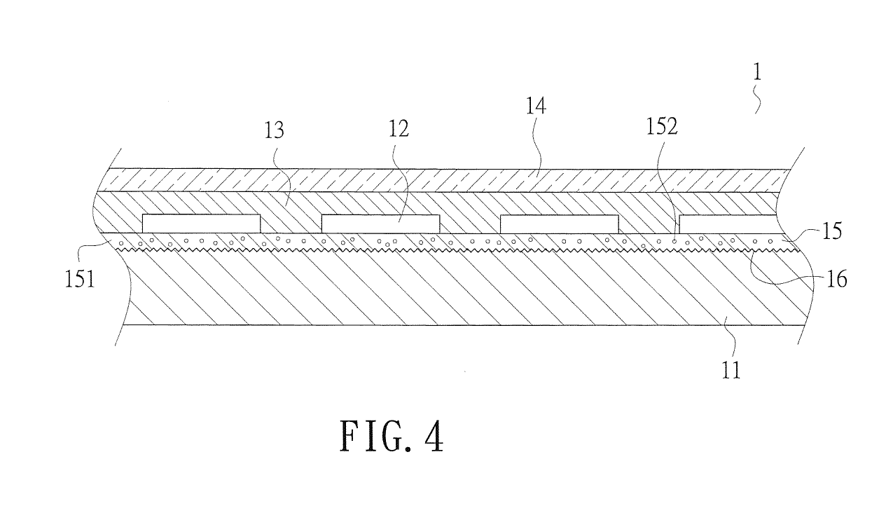

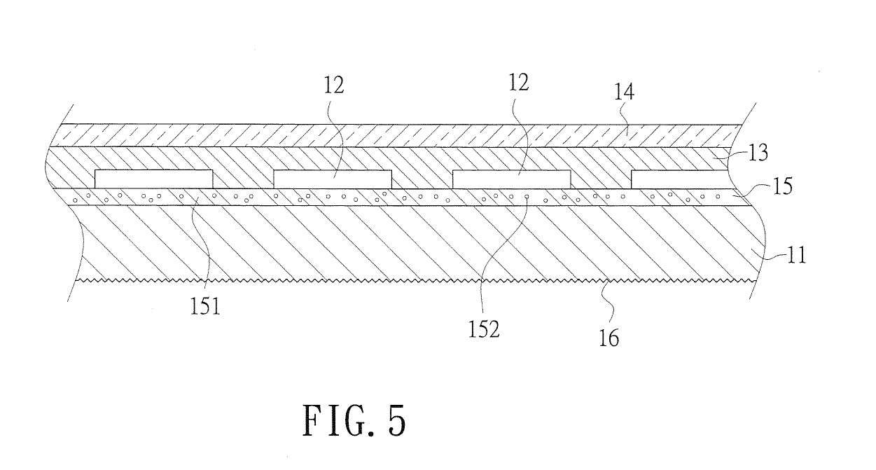

Referring to FIG. 4 and FIG. 5, to make light effectively reflect to the opaque region (A), a micro structure (16) is further provided, which can be disposed on the bottom of the diffusion film (15), on the top or on the bottom of the transparent substrate (11), or inside the transparent substrate (11). Moreover, the solar module (1) can connect in parallel with the supply mains and acts as an electric power source to provide objects in need of electric power, which is not only eco-friendly but also energy saving. The stored electric power can further provide for use of home appliances (e.g. a LED), so as to save cost of electric power.

According to the above description, in comparison with the traditional technique, a solar module having uniform light according to the present invention has the advantages as following:
1. The solar module having uniform light of the present invention can be utilized in plant factories which cultivate precious flowers as well as medicinal herbs and are in need of sufficient sunlight, in architecture industry (e.g. light absorption hoods), and in livestock industry (e.g. farmhouse).
2. The solar module having uniform light of the present invention has advantages of light weight and thin thickness. Moreover, the solar module can be combined with a lightweight frame assembled on the roof, and the lightweight frame can be further provided with a groove for easily assembling and replacing the solar module. Therefore, the present invention solves the problems, i.e. heavy weight and difficulty in replacement of solar modules.
3. The diffusion film of the solar module is added with scattering particles, and solar cell is rearranged in package. Therefore, the solar module allows sunlight to uniformly illuminate the inside of buildings.

What is claimed is:

1. A solar module having uniform light, comprising:
a transparent substrate;
at least one solar chip arranged on the transparent substrate for an opaque region by sheltering thereof and a light transmittable region surrounding the opaque region without sheltering thereof;
a transparent cover plate covered on the at least one solar chip;
a hot melt adhesive film for packaging the at least one solar chip and the transparent cover plate; and
a diffusion film disposed between the transparent substrate and the at least one solar chip;
characterized in that the light transmittable region has a transmittance ranging from 20% to 99% and a haze ranging from 10 Haze to 99 Haze, and the diffusion film scatters sunlight travelling through the light transmittable region to the opaque region sheltered by the solar chip to generate a uniform light.

2. The solar module having uniform light as claimed in claim 1, wherein a micro structure is disposed on the bottom of the diffusion film, on the top of the transparent substrate, on the bottom of the transparent substrate or inside the transparent substrate.

3. The solar module having uniform light as claimed in claim 1, wherein the light transmittable region accounts for 5% to 70% of the area of the solar module.

4. The solar module having uniform light as claimed in claim 1, wherein the at least one solar is selected from a group III-V solar chip, a monocrystalline silicon solar chip, a polycrystalline silicon solar chip or a CIGS solar chip.

5. The solar module having uniform light as claimed in claim 1, wherein the transparent cover plate is an ironless glass having a thickness less than 1 mm, and the transparent substrate is a transparent plastic film selected from a material of polyethylene terephthalate, acrylic, polycarbonate, polytetrafluoroethylene resin or ethylene-tetrafluoroethylene.

6. The solar module having uniform light as claimed in claim 1, wherein the diffusion film is made from a hot melt adhesive added with scattering particles, and the hot melt adhesive is selected from a material of polyethylene vinyl acetate resin, acrylic, polycarbonate or polyurea.

7. The solar module having uniform light as claimed in claim 1, wherein the solar module is utilized in a roof of a building, a shading hood or a solar power module.

8. The solar module having uniform light as claimed in claim 2, wherein the light transmittable region accounts for 5% to 70% of the area of the solar module.

9. The solar module having uniform light as claimed in claim 2, wherein the diffusion film is made from a hot melt adhesive added with scattering particles, and the hot melt adhesive is selected from a material of polyethylene vinyl acetate resin, acrylic, polycarbonate or polyurea.

10. The solar module having uniform light as claimed in claim 7, wherein the solar module is combined with a lightweight frame assembled on the roof of a building, and the lightweight frame is provided with a groove corresponding to the assembly of the solar module.

11. The solar module having uniform light as claimed in claim 7, wherein the solar module connects in parallel with the supply mains and acts as an electric power source to provide objects in need of electric power.
